(19) United States
(12) Patent Application Publication
(10) Pub. No.: US 2007/0278002 A1
(43) Pub. Date: Dec. 6, 2007

(54) Method and apparatus for a low thermal impedance printed circuit board assembly

(76) Inventors: Romi Mayder, San Jose, CA (US); Pamela Stellmacher, Cupertino, CA (US)

Correspondence Address: VERIGY, 4700 INNOVATION WAY, BLDG D1, FORT COLLINS, CO, 80528, US

(21) Appl. No.: 11/445,031

(22) Filed: May 31, 2006

(51) Int. Cl. H05K 1/11; H01R 12/04

(52) U.S. Cl. 174/262

(57) ABSTRACT

A low thermal impedance printed circuit board assembly compatible with surface mount assembly reflow solder processes is presented. The low thermal impedance printed circuit board assembly may have filled vias soldered directly to solder balls of the surface mount assembly.

### BACKGROUND

In today's super high density printed circuit board assemblies containing numerous surface mount semiconductor devices, the heat generated by these semiconductor devices has become problematic and is quite a challenge to remove effectively. For example, FIG. 1 illustrates a side cut-away view of part of a printed circuit assembly 10 with a device package 20 attached thereto, showing the heat path 55 from the device package 20 on the top side 12 of the printed circuit board 10 to the back side 14 of the circuit board 10, where heat dissipation means generally reside (not shown).

Many packages 20 have heat slugs (not shown) mounted inside the package 20 to help spread the heat generated by the semiconductor die (not shown). Then, the surface mount device 20 is soldered via solder balls 40 directly to solder pads 60 located on the printed circuit board 10. Attached to each solder pad 60 is a small, thin surface trace 70 referred to as a pin escape. These pin escape traces 70 are then connected to via holes 30 in the printed circuit board 10. Most device packages 20 allow for a multitude of solder pads 60, a multitude of pin escape traces 70, and a multitude of via holes 30. The back side 14 of the printed circuit board assembly 10 usually contains fans for air cooling, a metal block filled with liquid for water cooling, or other means to remove the heat (not shown).

One disadvantage of this approach to removing heat from a device package 20, is that the heat travels through a package solder ball 40, a solder pad 60, a pin escape trace 70 and a via hole 30, which significantly effects the path 55 of the heat flow. The solder pad 60 is not placed directly over the via hole 30, because when the solder reflows 50, it would potentially flow down the via hole 30 and starve the solder joint 45. The pin escape trace 70 and the solder pad 60 constitute major components of the thermal resistance for the thermal path 55. It is desirable to reduce the thermal impedance of the thermal path of high density surface mount printed circuit board assemblies.

### BRIEF DESCRIPTION OF THE DRAWINGS

An understanding of the present teachings can be gained from the following detailed description, taken in conjunction with the accompanying drawings of which:

FIG. 1 illustrates the thermal path from a surface mount package mounted on a top side of a printed circuit board assembly to the back side of the printed circuit board assembly according to the prior art.

FIG. 2 illustrates the thermal path from a surface mount package mounted on a top side of a printed circuit board assembly to the back side of the printed circuit board assembly according to an embodiment of the present invention.

FIG. 3 illustrates a process for manufacturing a printed circuit board assembly with high density surface mount device packages according to the present invention.

### DETAILED DESCRIPTION

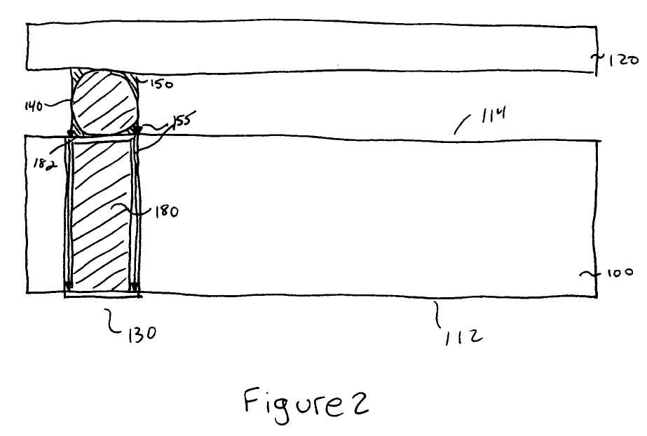

As shown in FIG. 2, the present invention removes the solder pad and the pin escape trace from the thermal path of the heat transferring from the top side of the printed circuit board assembly to the bottom side of the printed circuit board assembly. This is accomplished by filling the via holes 130 in the printed circuit board assembly 100 with copper epoxy 180. This epoxy may completely fill the via holes 130 and should deter solder from wicking down the via hole 130 during solder reflow when the surface mount package 120 is mounted to the printed circuit board assembly 100.

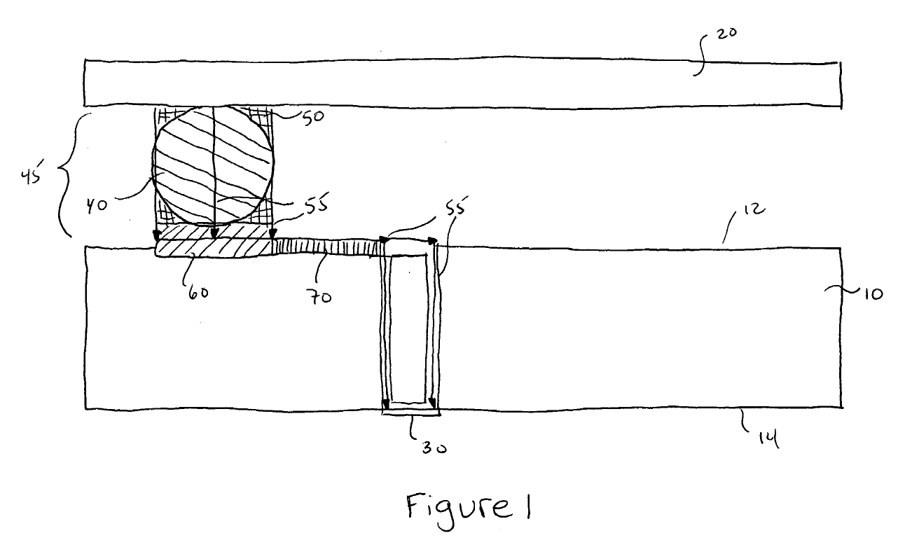

As shown in FIG. 2, the thermal path 155 from the surface mounted device package 120 on the top side 114 of the printed circuit board assembly 100 to the back side 112 of the printed circuit board assembly 100, where thermal dissipation means may reside, is significantly reduced. The thermal impedance of the thermal path 155 between the surface mount device package 120 and the back side of the printed circuit board assembly 100 is greatly reduced over the thermal impedance of the assembly in FIG. 1.

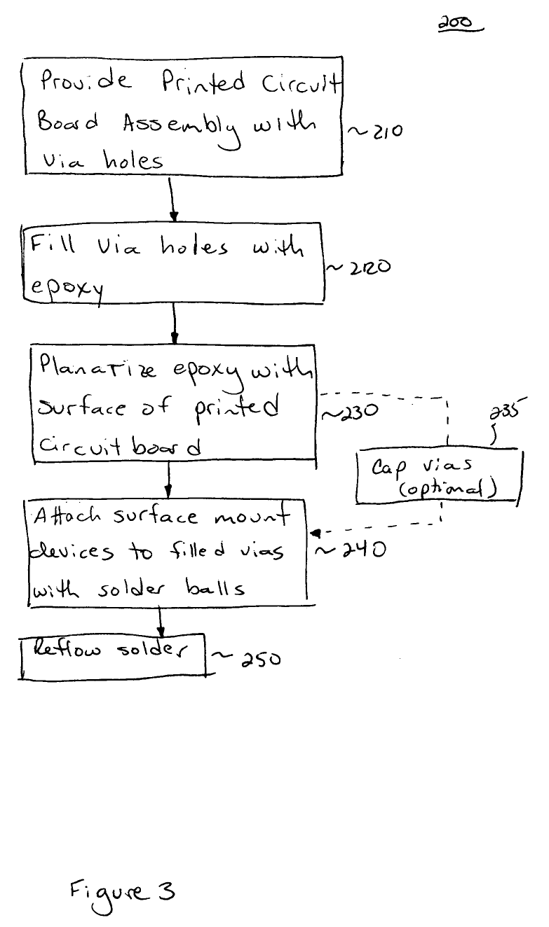

The epoxy mixture 180, may be copper epoxy or silver epoxy, or any known thermally conductive epoxy. The epoxy may also be non-thermally conductive. The via hole 130 structure may be filled with printed circuit board resin. Even thought the via hole is filled with non-thermally conductive material, the via hole structure will be significantly improved in terms of thermal impedance, due to the fact that the land pad or solder pad and pin escape traces are removed from the path between the solder ball and the via, since the solder ball can now be soldered directly to the via hole 130. As shown in the flow chart of FIG. 3, the via holes 130 of a provided (210) printed circuit board assembly are filled (220) with epoxy.

The epoxy 180 may be planarized (230) with the surface of the printed circuit board assembly 100 with any known planarizing process, such as a chemical etch process, followed by a mild, quick sanding operation. The surface 182 of the epoxy 180 may be plated (235) with copper nickel, and/or gold, which is known as capping the via, or the via may be left as is, depending on the application and desired thermal and electrical performance. The via hole 130 may then be attached (240) directly to the solder ball 140 of the surface mount device package 120 using a surface mount reflow process (250).

As will be readily appreciated, attaching device solder balls 140 directly to solid filled via holes 130 completely eliminates the pin escape traces and solder pads of the prior art, and also reduces the overall thermal path and thermal impedance of the printed circuit board assembly. This also permits the via hole 130 to be drilled to a larger diameter than in the past. The larger via hole 130 contains more copper due to the larger circumference of the via hole 130. This will improve the thermal impedance of the via hole 130.

It will be appreciated that other methods and materials may be used within the spirit of the present invention. For example, the vias may be filled with copper epoxy, silver epoxy, or non-thermally conductive printed circuit board resin. The planarization process may be omitted if the solder stencil is thick enough to compensate for the surface roughness of the filled via 130. If the planarization is done, this may be done by a process called nub removal, which involves a simple sanding process followed by a quick chemical polish. The vias 130 may be capped with copper, nickel, gold or with copper, pladium, gold. The nickel deposition may be electroplated or electroless deposition. The gold may be pure immersion gold or hard electroplated gold. The pladium may be either electroplated or electroless.

1. A low thermal impedance printed circuit board assembly comprising:
a printed circuit board with a top side and a bottom side, having a multitude of vias therein;
a surface mount device package having more than one solder ball attached to a top side of the printed circuit board;
wherein the more than one solder ball attached to the top side of the printed circuit board are attached directly to filled vias in the printed circuit board.

2. The low thermal impedance printed circuit board assembly according to claim 1, wherein the filled vias are filled with a copper epoxy.

3. The low thermal impedance printed circuit board assembly according to claim 1, wherein the filled vias are filled with a silver epoxy.

4. The low thermal impedance printed circuit board assembly according to claim 1, wherein the filled vias are filled with printed circuit board resin.

5. The low thermal impedance printed circuit board assembly according to claim 1, wherein the filled vias are planarized with the top surface of the printed circuit board.

6. The low thermal impedance printed circuit board assembly according to claim 5, wherein the planarized filled vias are capped.

7. The low thermal impedance printed circuit board assembly according to claim 6, wherein the planarized filled vias are capped with a material containing copper, nickel or gold.

8. A method for providing a low thermal impedance printed circuit board assembly comprising:
Providing a printed circuit board with via holes;
Filling the via holes with a thermally conductive material;
Attaching a surface mount device package with solder balls to the filled via holes; and
Reflowing the solder to attach the surface mount device package to the printed circuit board.

9. The method of providing a low thermal impedance printed circuit board assembly according to claim 8, wherein the via holes are filled with a copper epoxy material.

10. The method of providing a low thermal impedance printed circuit board assembly according to claim 8, further comprising capping the filled vias.

11. The method of providing a low thermal impedance printed circuit board assembly according to claim 10, wherein capping the filled vias comprises plating the filled vias with copper, nickel or gold.

12. The method of providing a low thermal impedance printed circuit board assembly according to claim 8, further comprising the step of planarizing the filled via hole with the surface of the printed circuit board.

13. The method of providing a low thermal impedance printed circuit board assembly according to claim 8, wherein the step of planarizing the surface of the printed circuit board comprises a chemical etch process.

14. The method of providing a low thermal impedance printed circuit board assembly according to claim 13, wherein the step of planarizing the surface of the printed circuit board further comprises a sanding operation.
